(19) United States
(12) Patent Application Publication
(10) Pub. No.: US 2026/0271621 A1
(43) Pub. Date: Sep. 10, 2026

(54) BONDED BODY, DEVICE, AND METHOD FOR PRODUCING BONDED BODY

(71) Applicant: NGK Corporation, Nagoya-shi (JP)

(72) Inventor: Takahiro KAWASAKI, Tajimi-shi (JP)

(21) Appl. No.: 19/666,442

(22) Filed: May 4, 2026

Related U.S. Application Data
(63) Continuation of application No. PCT/JP2024/038224, filed on Oct. 25, 2024.

(30) Foreign Application Priority Data
Nov. 9, 2023 (JP) 2023-191812

(51) Int. Cl. H10N 30/50; H10N 30/072

(52) U.S. Cl. CPC H10N 30/50; H10N 30/072

(57) ABSTRACT

A bonded body 1 includes a piezoelectric layer 11a made of a piezoelectric material, a dielectric layer 12 disposed below the piezoelectric layer 11a, and a support substrate 13 bonded to the piezoelectric layer 11a, with the dielectric layer 12 being sandwiched between the support substrate 13 and the piezoelectric layer 11a. The dielectric layer 12 includes a first silicon oxide layer 12a in contact with the piezoelectric layer 11a, and a second silicon oxide layer 12b that is positioned closer to the support substrate 13 than the first silicon oxide layer 12a is. The content of argon contained in the first silicon oxide layer 12a is larger than the content of argon contained in the second silicon oxide layer 12b. Consequently, a bonded body in which peeling of the piezoelectric substrate is unlikely to occur and a method for producing a bonded body are provided.

### CROSS-REFERENCE TO RELATED APPLICATION

This application is a continuation application of PCT/JP2024/038224 filed on Oct. 25, 2024, the entire contents of which are incorporated herein by reference.

### TECHNICAL FIELD

The present invention relates to a bonded body, device, and a method for producing a bonded body.

### BACKGROUND ART

A structure, in which a support substrate and a piezoelectric material substrate are pasted together, is used to realize a high-performance semiconductor element. In recent years, a structure, in which a silicon oxide layer is provided as an intermediate layer between a support substrate and a piezoelectric material substrate has been proposed to realize a device with even higher performance.

PTL 1 discloses a method for producing a composite wafer. This method for producing a composite wafer includes a step of implanting hydrogen atomic ions or hydrogen molecular ions from a surface to form an ion-implanted layer within an single-crystal oxide wafer, a step of performing a surface activation treatment on at least one of the ion-implanted surface of the single-crystal oxide wafer and the surface of the support wafer, and a step of pasting the ion-implanted surface of the single-crystal oxide wafer and the surface of the support wafer together to obtain a bonded body. Furthermore, this method for producing a composite wafer further includes a step of heat-treating the bonded body at a temperature of 90° C. or higher at which cracks will not occur, and a step of irradiating the heat-treated bonded body with visible light, thereby obtaining a single-crystal oxide thin film that is peeled along the ion-implanted layer and transferred onto the support wafer.

PTL 2 discloses a bonded body including a support substrate, a piezoelectric material substrate made of a material selected from the group consisting of lithium niobate, lithium tantalate, and lithium niobate-lithium tantalate, and a bonding layer that bonds the support substrate and the piezoelectric material substrate. The bonding layer material is silicon oxide. When the bonding layer is divided into a bonding portion on the piezoelectric material substrate side and a bonding portion on the support substrate side, and the nitrogen concentration in the bonding portion on the piezoelectric material substrate side is higher than the nitrogen concentration in the bonding portion on the support substrate side.

### CITATION LIST

### Patent Literature

PTL 1: JP-A-2016-225537
PTL 2: WO 2019/130895

### SUMMARY OF INVENTION

### Technical Problem

In conventional methods, a silicon oxide layer provided on a support substrate is formed, for example, by a thermal oxidation method.

However, where a silicon substrate having this silicon oxide layer is bonded to a piezoelectric material substrate using conventional techniques, and the piezoelectric substrate is then processed or heated, this can result in peeling of the piezoelectric substrate.

The present invention aims to provide a bonded body in which peeling of a piezoelectric substrate is unlikely to occur even when the piezoelectric substrate is, for instance, processed after the piezoelectric substrate and a support substrate were pasted together. The present invention also aims to provide a method for producing such a bonded body. Moreover, the present invention aims provide a device using such a bonded body.

### Solution to Problem

To solve the above problems, the present invention provides a bonded body comprising a piezoelectric layer made of a piezoelectric material, a dielectric layer disposed below the piezoelectric layer, and a support substrate bonded to the piezoelectric layer, with the dielectric layer being sandwiched between the support substrate and the piezoelectric layer, wherein the dielectric layer includes a first silicon oxide layer in contact with the piezoelectric layer and a second silicon oxide layer that is positioned closer to the support substrate than the first silicon oxide layer is, and a content of argon contained in the first silicon oxide layer is larger than a content of argon contained in the second silicon oxide layer. In this case, a bonded body can be provided in which peeling of the piezoelectric substrate is unlikely to occur even when the piezoelectric substrate is processed etc. after the piezoelectric substrate and the support substrate were pasted together.

Here, a thickness of the first silicon oxide layer can be 10 nm or more and 1000 nm or less. In this case, peeling of the piezoelectric substrate is even less likely to occur.

Furthermore, the arithmetic mean roughness of the main surface of the first silicon oxide layer can be 3 nm or less. In this case, peeling of the piezoelectric substrate is even less likely to occur.

In addition, the content of argon contained in the first silicon oxide layer can be 0.2% by mass or more and 1.0% by mass or less. In this case, the first silicon oxide layer can be formed by sputtering, and peeling of the piezoelectric substrate is even less likely to occur.

Furthermore, a thickness of the second silicon oxide layer can be 1000 nm or more and 20,000 nm or less. In this case, peeling of the piezoelectric substrate is even less likely to occur.

The present invention also relates to a device including the above-described bonded body. In this case, device yield is improved.

The present invention also relates to a method for producing a bonded body, the method including: a step of forming, by sputtering in which argon gas is introduced, a first silicon oxide layer on a main surface of a piezoelectric substrate made of a piezoelectric material; a step of forming a second silicon oxide layer on a main surface of the support substrate by thermally oxidizing a support substrate containing silicon; and a step of plasma activating and bonding the first silicon oxide layer and the second silicon oxide layer. In this case, a method for producing a bonded body can be provided in which peeling of the piezoelectric substrate is unlikely to occur even when the piezoelectric substrate is processed etc. after the piezoelectric substrate and the support substrate were pasted together.

Here, a step of mirror-polishing the main surface of the support substrate before thermally oxidizing the support substrate can also be included. In this case, a more uniform first silicon oxide layer can be formed, and when bonding is performed in the subsequent step, the layers can be pasted together more uniformly.

### Advantageous Effects of Invention

According to the present invention, it is possible to provide a bonded body in which peeling of a piezoelectric substrate is unlikely to occur even when the piezoelectric substrate is processed etc. after the piezoelectric substrate and a support substrate were pasted together, and also to provide a method for producing a bonded body. Furthermore, a device using the bonded body can also be provided.

### BRIEF DESCRIPTION OF DRAWINGS

FIG. 1 shows a bonded body of the present embodiment.

FIG. 2 is a flow chart explaining the method for producing the bonded body.

FIGS. 3A to 3E show the states for each step shown in FIG. 2.

FIG. 4 is an observation image of peeling of the LN substrate at Level 1.

FIG. 5 is an observation image of peeling of the LN substrate at Level 3.

FIG. 6 is an observation image of peeling of the LN substrate at Level 6.

FIG. 7 is a diagram showing a sputtering apparatus used when forming a silicon oxide film on the LN substrate by sputtering.

FIG. 8 shows observation images comparing the results before and after heating for Level 3 (Ar flow rate 1.3), Level 4 (Ar flow rate 1.35), and Level 6 (Ar flow rate 0.85).

FIG. 9 is a plot of the relationship between Ar content and change in the number of defects.

### DESCRIPTION OF EMBODIMENTS

Hereinafter, an embodiment of the present invention will be described in detail with reference to the appended drawings.

### <Explanation of Configuration of Bonded Body>

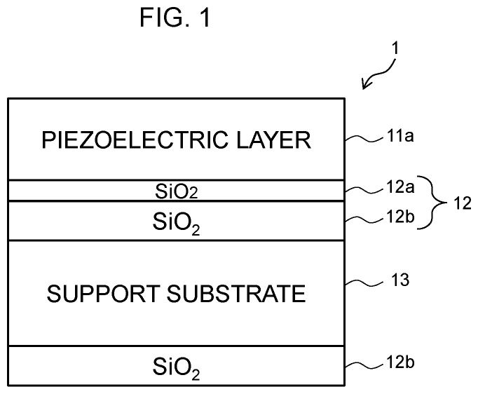

FIG. 1 shows a bonded body 1 of the present embodiment.

The bonded body 1 shown in the figure has a structure in which a piezoelectric layer 11a, a dielectric layer 12, and a support substrate 13 are laminated in this order from the top of the figure.

The piezoelectric layer 11a is made of a piezoelectric material. The piezoelectric material is selected depending on the application in which the bonded body 1 is to be used. Examples of the piezoelectric material include LiNbO₃ (LN) and LiTaO₃ (LT) but are not limited to these. Silicon (Si), gallium arsenide (GaAs), silicon carbide (Sic), gallium nitride (GaN), zinc oxide (ZnO), solid solution ceramics (PZT), and other materials may be selected as appropriate.

The dielectric layer 12 is disposed under the piezoelectric layer 11a. In the present embodiment, the dielectric layer 12 is mainly composed of SiO₂. In other words, the dielectric layer 12 can be said to be a SiO₂ film or a SiO₂ layer.

The dielectric layer 12 includes a first silicon oxide (SiO₂) layer 12a in contact with the piezoelectric layer 11a and a second silicon oxide (SiO₂) layer 12b located closer to the support substrate 13 than the first silicon oxide layer 12a. Furthermore, the content of argon contained in the first silicon oxide layer 12a is greater than the content of argon contained in the second silicon oxide layer 12b.

The content of argon contained in the first silicon oxide layer 12a is preferably 0.2% by mass or more and 1.0% by mass or less. Where the content of argon is 0.2% by mass or less, it becomes difficult to form the first silicon oxide layer 12a by sputtering. Furthermore, where the content of argon exceeds 1.0% by mass, the bonding strength between the piezoelectric layer 11a and the first silicon oxide layer 12a is likely to become insufficient, resulting in peeling of the piezoelectric layer 11a.

The second silicon oxide layer 12b contains almost no argon, below the detection limit.

The thickness of the first silicon oxide layer 12a is preferably 10 nm or more and 1000 nm or less. Where the thickness of the first silicon oxide layer 12a is less than 10 nm or more than 1000 nm, the bonding strength between the piezoelectric layer 11a and the first silicon oxide layer 12a is likely to become insufficient, resulting in peeling of the piezoelectric layer 11a.

Furthermore, the thickness of the second silicon oxide layer 12b is preferably 1000 nm or more and 20,000 nm or less. Where the thickness of the second silicon oxide layer 12b is less than 1000 nm or more than 20,000 nm, the bonding strength between the piezoelectric layer 11a and the first silicon oxide layer 12a is likely to become insufficient, resulting in peeling of the piezoelectric layer 11a.

The support substrate 13 provides support for the entire bonded body 1. Furthermore, the support substrate 13 is bonded to the piezoelectric layer 11a with the dielectric layer 12 sandwiched therebetween. As will be described in more detail below, the bonded body 1 is produced by forming the first silicon oxide layer 12a on the piezoelectric layer 11a, forming the second silicon oxide layer 12b on the support substrate 13, and then bonding the first silicon oxide layer 12a and second silicon oxide layer 12b together. Therefore, the first silicon oxide layer 12a formed on the piezoelectric layer 11a, and the second silicon oxide layer 12b formed on the support substrate 13 are bonded to form the dielectric layer 12, and it can be said that the piezoelectric layer 11a and support substrate 13 are bonded with the dielectric layer 12 interposed therebetween.

Any appropriate substrate may be used as the support substrate 13. The support substrate 13 may be made of a single crystal or a polycrystal. It may also be made of a metal.

The material constituting the support substrate 13 is preferably selected from the group consisting of silicon, sialon, sapphire, cordierite, mullite, glass, quartz, crystal, alumina, SUS, iron-nickel alloy (42 alloy), and brass. The thickness of the support substrate 13 is, for example, 0.2 mm to 1 mm, but any other appropriate thickness may be adopted.

The silicon may be single crystal silicon, polycrystal silicon, or high-resistance silicon. The support substrate 13 may also be SOI (Silicon on Insulator).

Typically, the sialon is a ceramic obtained by sintering a mixture of silicon nitride and alumina, and has a composition represented by, for example, Si_{6-w}Al_{w}O_{w}N_{8-w}. Specifically, sialon has a composition in which alumina is mixed into silicon nitride, and w in the formula indicates the mixing ratio of alumina. w is preferably 0.5 or more and 4.0 or less.

Typically, the sapphire is a single crystal having a composition of Al₂O₃, and the alumina is a polycrystalline body having a composition of Al₂O₃. The alumina is preferably translucent alumina.

Typically, the cordierite is a ceramic having a composition of 2MgO·2Al₂O₃·5SiO₂, and the mullite is a ceramic having a composition in the range of 3Al₂O₃·2SiO₂ to 2Al₂O₃·SiO₂.

### <Device>

The structure of the bonded body 1 shown in the figure can be used as the structure of various devices. Examples of devices include high-frequency devices, power semiconductors, semiconductor lasers, surface acoustic wave filters (SAW (Surface Acoustic Wave) filters), thin-film piezoelectric MEMS (Micro Electro Mechanical Systems), etc.

### <Description of Method for Producing Joint 1>

Next, a method for producing the bonded body 1 will be described.

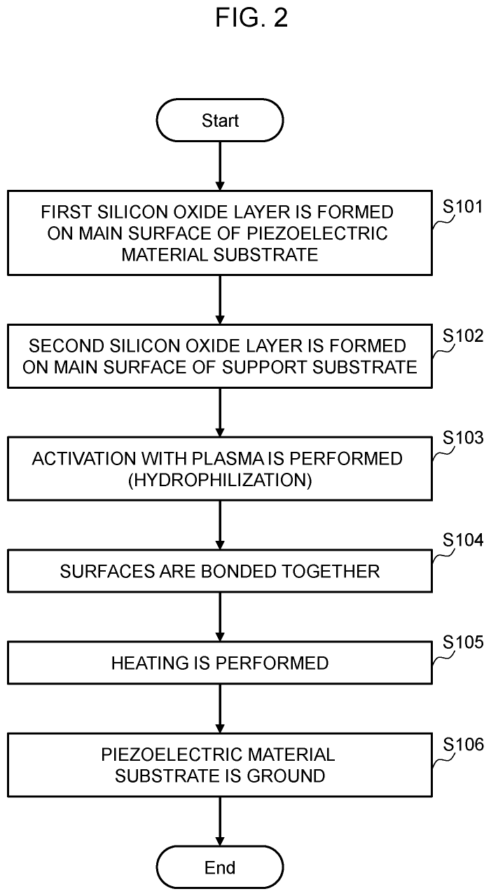

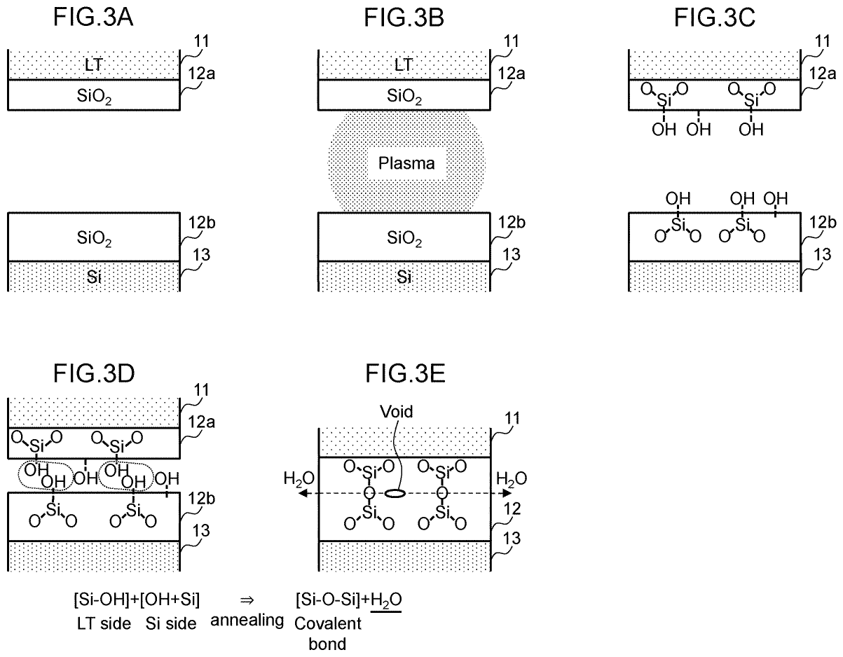

FIG. 2 is a flow chart explaining the method for producing the bonded body 1. Also, FIGS. 3A to 3E are diagrams showing the state for steps shown in FIG. 2.

First, the piezoelectric material substrate 11 made of a piezoelectric material is prepared, and the first silicon oxide layer 12a is formed on the main surface of the piezoelectric material substrate 11 (step 101). In the present embodiment, sputtering in which argon gas is introduced is performed in this step. As a result, the first silicon oxide layer 12a is formed on one main surface of the piezoelectric material substrate 11.

Specifically, the first silicon oxide layer 12a is formed by reactive sputtering using a reactive sputtering apparatus. That is, the piezoelectric material substrate 11 is placed in the reactive sputtering apparatus. A target made of silicon (Si) is also placed in the reactive sputtering apparatus. Argon (Ar) gas and oxygen (O₂) gas are then introduced into the reactive sputtering apparatus. The silicon constituting the target is then sputtered using a sputtering power supply to form a silicon film on the piezoelectric material substrate 11, and the silicon film is then oxidized by oxygen radicals generated by oxygen gas to form a silicon oxide (SiO₂) film. As a result, the first silicon oxide layer 12a containing silicon oxide (SiO₂) as a main component can be formed on the surface of the piezoelectric material substrate 11.

Next, the support substrate 13 containing silicon is prepared, and the second silicon oxide layer 12b is formed on the main surface of the support substrate 13 (step 102). In the present embodiment, the support substrate 13 is thermally oxidized in this step. As a result, the second silicon oxide layer 12b is formed over the entire surface of the support substrate 13, including the one main surface and the other main surface.

Specifically, the second silicon oxide layer 12b is formed by a heating treatment using a heating apparatus such as an oven. That is, the support substrate 13 is placed in an oven. Then, water vapor (H₂O) or oxygen (O₂) gas is introduced, and heating is performed at a predetermined temperature for a predetermined time, thereby forming a silicon oxide (SiO₂) film on the surface of the support substrate 13.

It is preferable that a step of mirror-polishing the main surface of the support substrate 13 be included before step 102. Mirror-polishing flattens the main surface of the support substrate 13, on which the second silicon oxide layer 12b is to be formed. As a result, a more uniform second silicon oxide layer 12b can be formed, and when bonding is performed in the subsequent step, the layers can be pasted together more uniformly.

Steps 101 and 102 can be considered dielectric layer formation steps (FIG. 3A) for forming the first silicon oxide layer 12a and second silicon oxide layer 12b on the main surfaces of the piezoelectric material substrate 11 and support substrate 13. The order of steps 101 and 102 may be reversed.

The first silicon oxide layer 12a and second silicon oxide layer 12b can also be polished and flattened. As a result, when bonding is performed in the subsequent step, the bonding strength is improved.

Next, the first silicon oxide layer 12a and second silicon oxide layer 12b are activated by plasma (step 103: activation step) (FIG. 3B). N₂ plasma can be used. As a result, as shown in FIG. 3C, the SiO₂ constituting the first silicon oxide layer 12a and second silicon oxide layer 12b is activated, generating hydroxyl groups (OH groups) as hydrophilic functional groups. Therefore, this step can also be considered a hydrophilization step of hydrophilizing the surfaces of the first silicon oxide layer 12a and second silicon oxide layer 12b by plasma.

Then, the surfaces of the first silicon oxide layer 12a and second silicon oxide layer 12b after the activation step are bonded together (step 104: bonding step) (FIG. 3D). Bonding is performed, for example, by bringing the surfaces of the first silicon oxide layer 12a and second silicon oxide layer 12b into contact with each other and pressing them together with a predetermined pressure. This bonds the piezoelectric material substrate 11 and the support substrate 13 together with the first silicon oxide layer 12a and second silicon oxide layer 12b interposed therebetween.

Then, the bonded piezoelectric material substrate 11 and support substrate 13 are heated (step 105: heating step) (FIG. 3E). For example, the bonded piezoelectric material substrate 11 and support substrate 13 are placed in a heating device such as an oven, and heating is performed at a predetermined temperature and time. The hydroxyl groups generated on the surfaces of the first silicon oxide layer 12a and second silicon oxide layer 12b are covalently bonded by heating. The first silicon oxide layer 12a and second silicon oxide layer 12b are then integrated to form the dielectric layer 12. As a result, the piezoelectric material substrate 11 and the support substrate 13 are firmly bonded with the dielectric layer 12 interposed therebetween. At this time, the reaction [Si—OH]+ [OH+Si]→[Si—O—Si]+H₂O occurs.

The heating step can also be considered as a step (annealing step) for annealing the bonded piezoelectric material substrate 11 and support substrate 13.

Next, the heated piezoelectric material substrate 11 is ground (step 106: grinding step). In the present embodiment, the piezoelectric material substrate 11 is thinned by grinding to form the piezoelectric layer 11a shown in FIG. 1. The support substrate 13 may also be ground, or the edges of the piezoelectric material substrate 11 and support substrate 13 may be ground. By the above steps, the bonded body 1 can be produced.

### EXAMPLES

A silicon substrate was prepared as the support substrate 13, and both the front and back surfaces were polished to a mirror finish. A silicon oxide film (SiO₂) was then formed as the second silicon oxide layer 12b on this silicon substrate by thermal oxidation. The silicon oxide film had a thickness of 1000 nm.

Next, a lithium niobate (LN) substrate was prepared as the piezoelectric material substrate 11, and a silicon oxide film was formed as the first silicon oxide layer 12a on the LN substrate. The silicon oxide film on the LN substrate was formed by sputtering, and the thickness of the silicon oxide film was varied according to the conditions shown in Table 1. Specifically, the thickness was varied over seven levels (Levels 1 to 7): 0 nm, 5 nm, 10 nm, 15 nm, 20 nm, 1000 nm, and 1500 nm.

The silicon substrate and LN substrate were then plasma activated and bonded to form a wafer. The pasted wafer was then heated in an inert oven in a non-oxidizing atmosphere at 100° C. for 10 h, and the surface of the LN substrate was then polished with a grinder using a #1000 grinding wheel.

Table 1 shows the results of the evaluation of whether the LN substrate surface peeled after polishing.

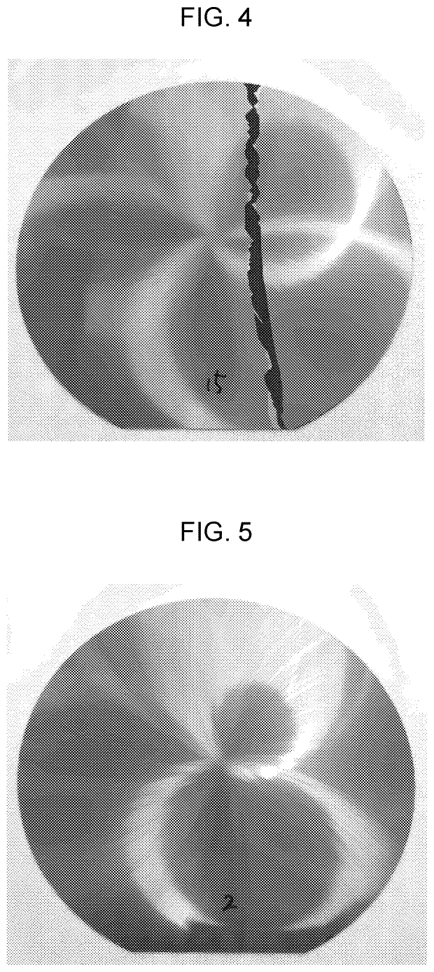

When the silicon oxide film thickness was 0 nm (no silicon oxide film was formed on the LN substrate) (Level 1), peeling of the LN substrate was observed after polishing. In this case, peeling is thought to occur due to insufficient bonding strength between the LN substrate and the silicon oxide film on the support substrate 13 side. FIG. 4 shows an observation image of the peeling of the LN substrate in this case. As shown in FIG. 4, it is clear that significant peeling has occurred.

On the other hand, it was found that the LN substrate could be processed without peeling if the thickness of the silicon oxide film on the LN substrate side was 10 nm or more. As an example of this case, FIG. 5 shows an observation image of the state of the LN substrate when the silicon oxide layer was 10 nm thick (Level 3). As can be seen in FIG. 5, no peeling occurred.

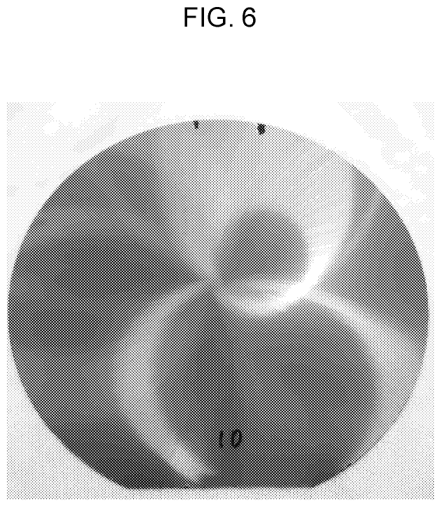

Furthermore, when the silicon oxide film was 1000 nm thick, slight peeling was observed after polishing. This is thought to be because the arithmetic mean roughness (Ra) increased when the film was thicker. FIG. 6 shows an observation image of the peeling of the LN substrate at this time (Level 6). As shown in FIG. 6, small peeling can be seen on the periphery of the LN substrate. However, peeling of this magnitude does not pose a problem for subsequent use as a wafer and is within the acceptable range.

When the silicon oxide film was 1500 nm thick, unacceptable peeling was observed after polishing.

From these results, it can be seen that to increase the bonding strength between the LN substrate and the silicon oxide film formed on the LN substrate, it is desirable to form a silicon oxide film having a thickness of 10 nm or more and 1000 nm or less on the LN substrate. Furthermore, from the perspective of arithmetic mean roughness (Ra), it can be said based on Table 1 that the arithmetic mean roughness (Ra) of the silicon oxide film is preferably 3 nm or less.

TABLE 1

| | Thickness of | | | | |
|---|---|---|---|---|---|
| | SiO₂ [A1.1]film on | | Ra of SiO₂ | | |
| Level | LN substrate side | | [A2.1] film | | State after polishing |
| 1 | 0 | nm | — | | Peeling after polishing |
| 2 | 5 | nm | 0.14 | nm | Slight peeling after polishing |
| 3 | 10 | nm | 0.18 | nm | None |
| 4 | 15 | nm | 0.16 | nm | None |
| 5 | 20 | nm | 0.17 | nm | None |
| 6 | 1000 | nm | 2.9 | nm | Slight peeling after polishing |
| 7 | 1500 | nm | 3.8 | nm | Peeling after polishing |

Next, to further improve bonding strength, it was evaluated using an accelerated test while optimizing sputtering conditions.

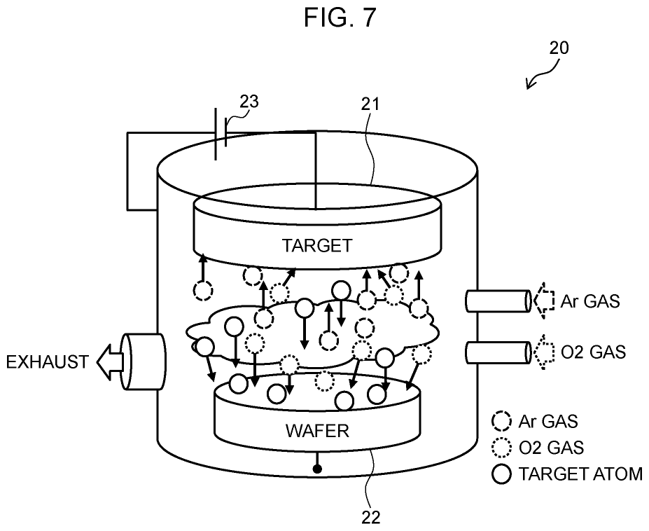

FIG. 7 shows a sputtering apparatus 20 used to form a silicon oxide film on an LN substrate by sputtering.

The illustrated sputtering apparatus 20 uses silicon (Si) as a target 21 and performs reactive sputtering on an LN substrate 22. A sputtering power supply 23 is connected to the target 21 and LN substrate 22, applying a voltage between them. The sputtering apparatus 20 is fed with argon (Ar) gas as an inert gas and oxygen (O₂) gas as a reactive gas, to perform reactive sputtering. In other words, an electric discharge in the argon gas generates positive ions that collide with the target 21, which serves as the cathode. Silicon that makes up the target 21 is thereby ejected and adheres to the LN substrate 22. Similarly, an electric discharge in the oxygen gas generates oxygen radicals, which then undergo an oxidation reaction with the silicon adhered to the LN substrate 22, forming silicon oxide (SiO₂). This results in the formation of a silicon oxide film primarily composed of silicon oxide on the surface of the LN substrate 22.

Examples of parameters of the sputtering apparatus 20 include the argon gas flow rate (Ar flow rate), the oxygen gas flow rate (O₂ flow rate), and the discharge output of the target 21. In the present embodiment, the Ar flow rate was varied, while the other conditions were kept constant, to form a 10 nm silicon oxide film on the LN substrate 22. As shown in Table 2, the Ar flow rate was varied at seven levels (Levels 1 to 7), with a standard condition being 1. Meanwhile, the silicon substrate was thermally oxidized, as in the previous example, and a 1000 nm silicon oxide film was formed under uniform film formation conditions.

TABLE 2

| Level | Ar flow rate |
|---|---|
| 1 | 1 |
| (Standard) | |
| 2 | 1.2 |
| 3 | 1.3 |
| 4 | 1.35 |
| 5 | 0.9 |
| 6 | 0.85 |
| 7 | 0.3 |

Then, similarly, the silicon oxide film surfaces on both the silicon substrate and the LN substrate 22 were activated, bonded, and heated. The surface of the LN substrate 22 was then polished until the film thickness of the LN substrate 22 was 1000 nm. At this point in time, no peeling, such as before, of the LN substrate 22 was observed. Next, the wafer in which these were pasted together was heated in an oven at 500° C. for 10 h. The surface of the LN substrate 22 was visually observed before and after heating by using an optical appearance inspection device to evaluate the number of surface defects, i.e., the degree of progress of LN peeling. Defects 10 μm or more in size were counted.

Table 3 shows the change in the number of defects before and after heating. It was found that the number of defects increased when the Ar flow rate exceeded 1.3. In this case, it is believed that the bonding strength between the LN substrate and the silicon oxide film becomes insufficient as the number of defects increases.

TABLE 3

| | | Number of | Number of | Increase | Ar |
|---|---|---|---|---|---|
| | | defects | defects | in the | content |
| | Ar | before | after | number | in film |
| Level | flow rate | heating | heating | of defects | (% by mass) |
| 1 | 1 | 27 | 34 | 7 | 0.77 |
| (Standard) | | | | | |
| 2 | 1.2 | 38 | 48 | 10 | 0.9 |
| 3 | 1.3 | 41 | 202 | 161 | 1.02 |
| 4 | 1.35 | 46 | 674 | 628 | 1.18 |
| 5 | 0.9 | 28 | 30 | 2 | 0.7 |
| 6 | 0.85 | 42 | 45 | 3 | 0.67 |
| 7 | 0.3 | 39 | 42 | 3 | 0.2 |

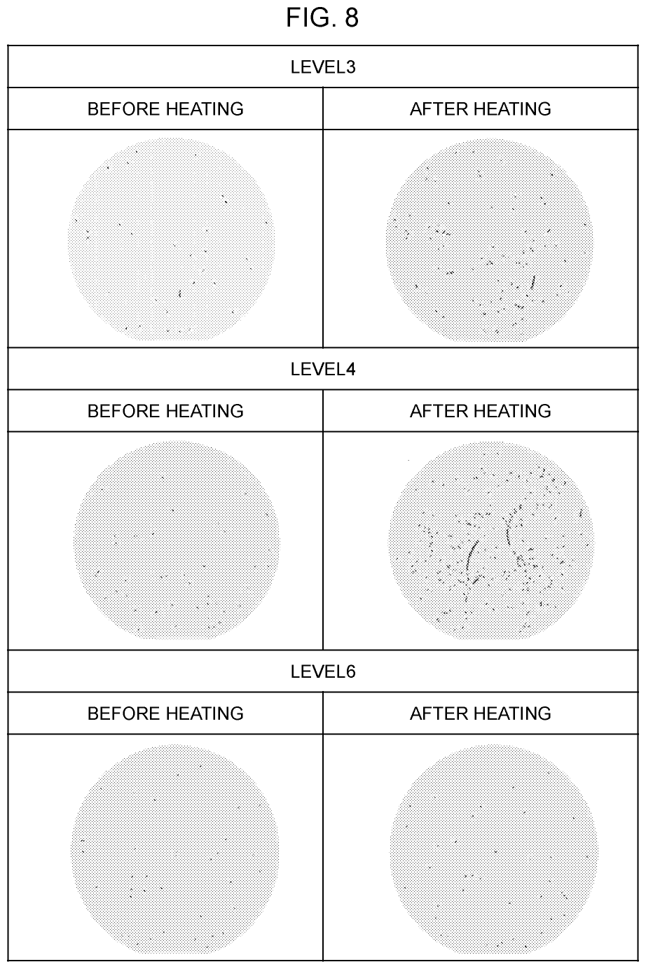

FIG. 8 shows observation images comparing the results before and after heating for Level 3 (Ar flow rate 1.3), Level 4 (Ar flow rate 1.35), and Level 6 (Ar flow rate 0.85). These observation images clearly show that the number of defects increases when the Ar flow rate is high.

Next, the Ar content in the silicon oxide films of Levels 1 to 7 was analyzed using Rutherford Backscattering Spectrometry (RBS). The results are shown in Table 3.

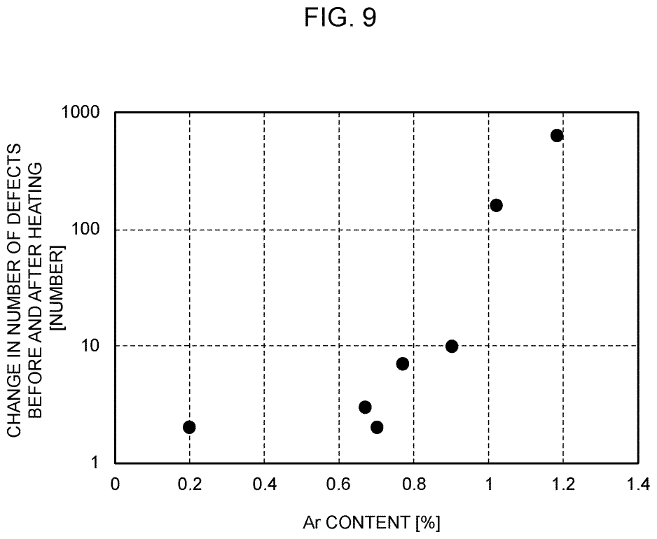

FIG. 9 is a plot of the relationship between Ar content and change in the number of defects.

It is clear that keeping the Ar content 18 by mass or less prevents an increase (100 or more) in the number of defects. Level 7 showed a low number of defects, but the Ar flow rate was kept to a minimum, making the plasma unstable during sputtering. For this reason, an Ar content of 0.2% by mass, which corresponded to this level, is the minimum amount of Ar contained in a silicon oxide film of the range in which the film can be formed by sputtering.

Furthermore, for reference, the RBS analysis of Ar content in the film was also performed for the silicon oxide film on the silicon substrate side formed by thermal oxidation, but the amount of argon was below the detection limit.

Argon in a silicon oxide film formed by sputtering can be released as outgas under heating. A silicon oxide film containing a large amount of argon will release argon gas as outgas under heating, and this is thought to be the starting point for peeling off the LN substrate 22.

From the above, it can be seen that in order to improve the bonding strength between the LN substrate 22 and the silicon oxide film formed on the LN substrate 22, it is desirable for the Ar content in the silicon oxide film to be 0.2% by mass or more and 1.0% by mass or less.

Next, the thickness of the silicon oxide film formed by thermal oxidation on the silicon substrate side was varied among five levels (Levels 1 to 5): 1000 nm, 10,000 nm, 15,000 nm, 20,000 nm, and 23,000 nm, and the degree of progress of LN peeling was evaluated. The film formation condition for the silicon oxide film on the LN substrate 22 was Level 1 in Table 3, and the film thickness was uniform at 10 nm. Next, the wafer obtained by pasting was heated in an oven at 500° C. for 10 h in the same manner as described above. The degree of progress of LN peeling was then evaluated before and after heating using an optical appearance inspection device.

The evaluation results are shown in Table 4.

It was found that the number of defects in the silicon oxide film on the silicon substrate side tended to increase slightly when the thickness exceeded 20,000 nm.

Table 4 also shows the arithmetic mean roughness (Ra) of the silicon oxide film surface on the silicon substrate side. The arithmetic mean roughness (Ra) tends to increase as the silicon oxide film thickness increases, and the degree of progress of LN peeling is thought to have changed under the effect of this increase. Polishing the surface of the silicon oxide film can be considered as means for reducing the arithmetic mean roughness (Ra), but in this case, the polishing process may cause the silicon oxide film to absorb moisture, raising concerns about outgassing during heating, such as mentioned above. Therefore, in order to bond without polishing, it is preferable to keep the thickness at around 20,000 nm.

TABLE 4

| | Thickness | | | | | |
|---|---|---|---|---|---|---|
| | of | | Number | Number | Increase | Ra of |
| | SiO₂[A3.1] | | of defects | of defects | in the | SiO₂ |
| | film on LN | | before | after | number of | [A4.1] |
| Level | substrate side | | heating | heating | defects | film |
| 1 | 1000 | nm | 27 | 34 | 7 | 0.23 nm |
| (Standard) | | | | | | |
| 2 | 10000 | nm | 42 | 69 | 27 | 0.47 nm |
| 3 | 15000 | nm | 37 | 65 | 28 | 0.55 nm |
| 4 | 20000 | nm | 29 | 138 | 109 | 0.63 nm |
| 5 | 23000 | nm | 41 | 229 | 188 | 0.95 nm |

The present embodiment has been described above, but the technical scope of the present invention is not limited to the scope described in the embodiment. It is clear from the claims that the technical scope of the present invention is also inclusive of embodiments obtained by various modifications or improvements of the above embodiment.

### REFERENCE SINGS LIST

1 Bonded body
11 Piezoelectric material substrate
11a Piezoelectric layer
12 Dielectric layer
12a First silicon oxide layer
12b Second silicon oxide layer
13 Support substrate
20 Sputtering apparatus
21 Target
22 LN substrate

1. A bonded body comprising:
a piezoelectric layer made of a piezoelectric material;
a dielectric layer disposed below the piezoelectric layer; and
a support substrate bonded to the piezoelectric layer, with the dielectric layer being sandwiched between the support substrate and the piezoelectric layer, wherein
the dielectric layer includes a first silicon oxide layer in contact with the piezoelectric layer, and a second silicon oxide layer that is positioned closer to the support substrate than the first silicon oxide layer is, and a content of argon contained in the first silicon oxide layer is larger than a content of argon contained in the second silicon oxide layer.

2. The bonded body according to claim 1, wherein a thickness of the first silicon oxide layer is 10 nm or more and 1000 nm or less.

3. The bonded body according to claim 1, wherein an arithmetic mean roughness of a main surface of the first silicon oxide layer is 3 nm or less.

4. The bonded body according to claim 1, wherein the content of argon contained in the first silicon oxide layer is 0.2% by mass or more and 1.0% by mass or less.

5. The bonded body according to claim 1, wherein a thickness of the second silicon oxide layer is 1000 nm or more and 20,000 nm or less.

6. A device comprising the bonded body according to claim 1.

7. A method for producing a bonded body, the method comprising:
a step of forming, by sputtering in which argon gas is introduced, a first silicon oxide layer on a main surface of a piezoelectric substrate made of a piezoelectric material;
a step of forming a second silicon oxide layer on a main surface of the support substrate by thermally oxidizing a support substrate containing silicon; and
a step of plasma activating and bonding the first silicon oxide layer and the second silicon oxide layer.

8. The method for producing a bonded body according to claim 7, the method further comprising a step of mirror-polishing the main surface of the support substrate before thermally oxidizing the support substrate.
